(19) United States
(12) Patent Application Publication
(10) Pub. No.: US 2007/0241439 A1
(43) Pub. Date: Oct. 18, 2007

(54) RFID package structure

(76) Inventors: Yu-Peng Chung, Hsin-Tien City (TW); Kuo-Tung Chang, Hsin-Tien City (TW); En-Ming Chen, Hsin-Tien City (TW); Chia-Wei Li, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/783,760

(22) Filed: Apr. 12, 2007

(30) Foreign Application Priority Data
Apr. 14, 2006 (TW) 95113475

(51) Int. Cl. H01L 23/02; G08B 13/14

(52) U.S. Cl. 257/679; 340/572.8

(57) ABSTRACT

The present invention provides a radio frequency identification (RFID) package structure for improving a low data reading rate of the conventional RFID transponder structure to overcome the disadvantage of the prior art, and packages a RFID die by an adhesive according to a package technology. The RFID package structure provides different ways of improving the data reading capability, such as adding a capacitor. The capacitance of the capacity can be adjusted to provide a RFID package structure applicable for different frequencies, or the RFID package structure formed by the structure of a single substrate together with the use of an adhesive can be used for producing the RFID package structure to lower the manufacturing cost.

### BACKGROUND OF THE INVENTION

1. Field of the invention The present invention relates to a package structure, and more particularly to a radio frequency identification (RFID) package structure.

2. Description of Related Art RFID is an advanced wireless identification technology that can transmit information to a computer network through a microchip-based “tag” that is attached to or incorporated in a product for identifying, tracking and confirming the conditions of the product.

A RFID system is comprised of two types of devices: a transponder and a reader, such as a card or a tag, which is a passive response device. If the RFID system is turned on, the reader will generate a wireless signal of a specific frequency to activate a program stored in a chip of the transponder in order to generate radio frequency waves, and an ID code stored in a memory will be transmitted back to the reader and decoded by a host computer for the function of determining the completion of the identification.

A conventional RFID transponder is made by a direct chip attach (DCA) process and connected to a device such as a printed circuit board (PCB) or an organic flexible substrate. The direct chip attach (DCA) process is a low-price packaging process that attaches a chip directly on a substrate without encapsulating the chip. However, the lithographic process for forming metal wires is one of the expensive processes for producing RFID transponders. U.S. Pat. No. 6,529,408B1 disclosed a related technology to lower the manufacturing cost, and such patented technology uses a nozzle to spray a conductive adhesive to produce an antenna pattern, and uses the direct chip attach (DCA) process to electrically connect a RFID tag having a metal bump to a portion of the antenna pattern, and then the metal bump becomes a portion of the antenna pattern, and such arrangement can waive the lithographic process as well as the manufacturing cost.

Although the direct chip attach (DCA) process can lower the manufacturing cost, the hit rate of receiving data from a RFID transponder by a RFID reader in actual applications of a RFID system is approximately 60% to 70% only. Furthermore, the moisture resisting capability and the overall structural strength of the RFID transponder are not as good either.

### SUMMARY OF THE INVENTION

In view of the foregoing shortcomings of the prior art, the present invention provides a RFID package structure to overcome the shortcomings.

The RFID package structure in accordance with the present invention comprises a first substrate, a RFID die, a second substrate, at least one first circuit pattern, at least one second circuit pattern and an adhesive, wherein the first circuit pattern is formed at an upper surface of the second substrate, and the first circuit pattern includes an antenna pattern, and the second circuit patterns are formed on a lower surface of the second substrate, and the second circuit pattern includes an antenna pattern or no pattern, so as to produce a complete RFID structure.

The RFID package structure in accordance with a preferred embodiment of the present invention comprises a first substrate, a RFID die, a second substrate, at least one first antenna pattern, at least one second antenna pattern and an adhesive, wherein the first antenna patterns are formed on an upper surface of the first substrate, and the second antenna patterns are formed on an upper surface of the second substrate, so that the overall area of the RFID structure can be reduced.

The RFID package structure in accordance with another preferred embodiment comprises a first substrate, a RFID die, a second substrate, a capacitor and at least one first antenna pattern, wherein the first antenna patterns are formed on an upper surface of the second substrate to produce a complete RFID structure, and the capacitor constitutes a LC loop circuit for adjusting the capacitance of the capacitor to satisfy the requirement of different frequencies.

The RFID package structure in accordance with a further preferred embodiment comprises a first substrate, a RFID die, a second substrate, a capacitor, at least one first antenna pattern, at least one second antenna pattern and an adhesive, wherein the first antenna patterns are formed on an upper surface of the first substrate, and the second antenna patterns are formed on an upper surface of the second substrate to produce a complete RFID structure, and the capacitor constitutes a LC loop circuit for adjusting the capacitance of the capacitor to satisfy the requirement of different frequencies.

In another preferred embodiment of the invention, the RFID package structure comprises a RFID die, a first substrate, a capacitor, at least one first antenna pattern and an adhesive, wherein the first antenna pattern is formed on the upper surface of the first substrate to produce a complete RFID structure, and the capacitor constitutes a LC loop circuit for adjusting the capacitance of the capacitor to satisfy the requirement of different frequencies, and the adhesive is used for wrapping the entire RFID package.

The RFID package structure of the present invention can achieve the effects of improving the moisture resisting capability, increasing the data reading rate and providing a higher overall structural strength of the RFID transponder.

To make it easier for our examiner to understand the innovative features and technical content, we use preferred embodiments together with the attached drawings for the detailed description of the invention, but it should be pointed out that the attached drawings are provided for reference and description but not for limiting the present invention.

### BRIEF DESCRIPTION OF THE DRAWINGS

FIG. 1A is a schematic view of a RFID package structure of a first preferred embodiment of the present invention;

FIG. 1B is a schematic view of a RFID structure of a first preferred embodiment of the present invention;

FIG. 1C is a flow chart of a manufacturing method of a RFID package structure according to a first preferred embodiment of the present invention;

FIG. 2 is a schematic view of a RFID package structure of a second preferred embodiment of the present invention;

FIG. 3 is a schematic view of a RFID package structure of a third preferred embodiment of the present invention;

FIG. 4A is a schematic view of a RFID package structure of a fourth preferred embodiment of the present invention;

FIG. 4B is a flow chart of a manufacturing method of a RFID package structure according to a fourth preferred embodiment of the present invention;

FIG. 5 is a schematic view of a RFID package structure of a fifth preferred embodiment of the present invention;

FIG. 6 is a schematic view of a RFID package structure with a single substrate of a first preferred embodiment of the present invention;

FIG. 7 is a flow chart of a manufacturing method of a RFID package structure with a single substrate according to the present invention;

FIG. 8 is a schematic view of a RFID package structure with a single substrate of a second preferred embodiment of the present invention; and

FIG. 9 is a schematic view of a RFID package structure with a single substrate of a third preferred embodiment of the present invention.

### DETAILED DESCRIPTION OF THE PREFERRED EMBODIMENTS

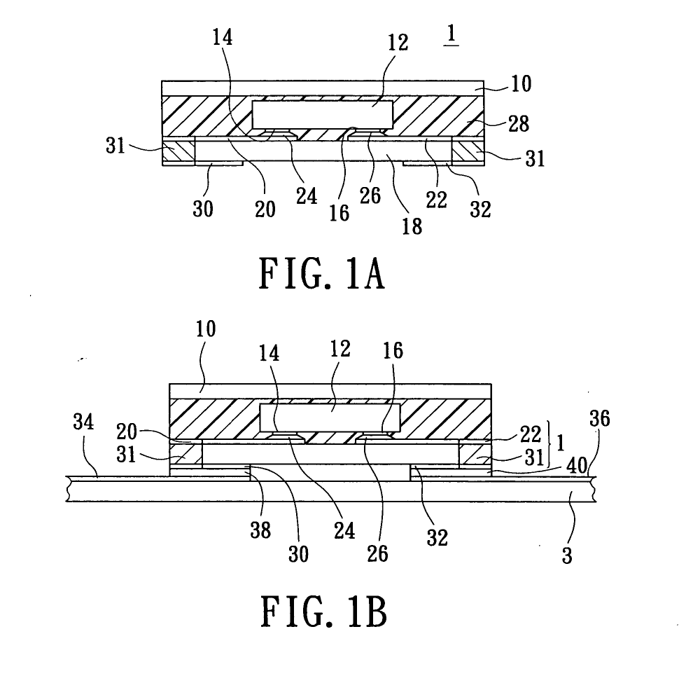

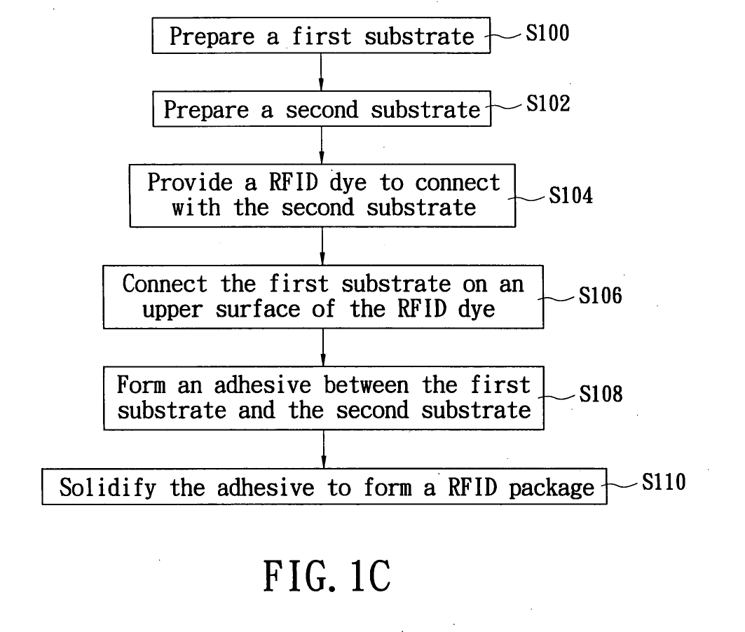

Referring to FIG. 1A for a schematic view of a RFID package structure in accordance with a first preferred embodiment of the present invention, the RFID package structure 1 comprises a first substrate 10, a RFID die 12, a second substrate 18, at least one first circuit pattern 20, 22 and an adhesive 28.

The first substrate 10 and the second substrate 18 are made of a soft organic material or a glass fiber material, and the soft organic material includes a combination of polymer, polyester and other similar materials, or a hard material such as any combination of ceramics. The RFID die 12 comprises at least one I/O pad 14, 16 disposed at a lower surface of the RFID die 12, and the RFID die 12 is installed at a lower surface of the first substrate 10. The first circuit patterns 20, 22 are formed at an upper surface of the second substrate 18, and each first circuit pattern 20, 22 includes a first connecting point 24, 26 and is connected to the I/O pad 14, 16 through the first connecting point 24, 26 for electrically connecting the RFID die 12, wherein at least one second circuit pattern 30, 32 is formed, and an adhesive 28 is filled between the first substrate 10 and the second substrate 18. The first circuit patterns 20, 22 and the second circuit patterns 30, 32 can be conducted vertically by at least one conducting region 31 according to the functions and requirements of the circuits, so that the first circuit patterns 20, 22 and the second circuit patterns 30, 32 can be connected electrically.

Referring to FIG. 1B for a schematic view of a RFID package structure in accordance with a first preferred embodiment of the present invention, the RFID structure comprises the foregoing RFID package structure 1 and a third substrate 3, wherein the internal structure of the RFID package structure 1 has been described above, and thus will not be described again here. However, the third substrate 3 has at least one antenna pattern 34, 36 disposed at an upper surface of the third substrate 3, and each antenna pattern 34, 36 has a second connecting point 38, 40 for electrically connecting the antenna patterns 34, 36 and the second circuit patterns 30, 32, and the RFID package structure 1 and the third substrate 3 can be combined by an automated machine easily available in the market. The third substrate 3 can be made of a soft organic material such as a combination of polymer, polyester and other similar materials, or a hard material such as any combination of ceramics.

Referring to FIG. 1C a flow chart of a manufacturing method of a RFID package structure according to a first preferred embodiment of the present invention, the manufacturing procedure comprises the steps of: preparing a first substrate 10 (S100); preparing a second substrate 18 (S102), wherein the second substrate 18 forms at least one first circuit pattern 20, 22 on an upper surface of the second substrate 18, and each first circuit pattern 20, 22 has a first connecting point 24, 26; combining a RFID die 12 with the second substrate 18 (S104), wherein the RFID die 12 has at least one I/O pad 14, 16 at a lower surface of the RFID die 12, and the RFID die can be combined with the second substrate 18 by a soldering method or a baking method depending on the material of the first connecting point 24, 26, wherein the soldering method will be adopted if the first connecting points 24, 26 are made of a solder paste, and the baking method will be adopted if the first connecting points 24, 26 are made of a conductive adhesive.

While Step (S104) is being carried out, the first substrate 10 is integrated with an upper surface of the RFID die 12 by a soldering method or a baking method (S106), and an adhesive 28 is formed between the first substrate 10 and the second substrate 18 by an adhesion method or an ink-jet method, and the adhesive 28 can be a liquid epoxy resin (S108), and finally the baking method is adopted to solidify the adhesive 28 to form the RFID package 1 (S110).

The RFID package structure in accordance with the first preferred embodiment of the present invention is characterized in that the RFID die 12 is packaged to achieve the effects of improving the moisture resisting capability, increasing the data reading rate, and providing better overall structural strength of the RFID transponder.

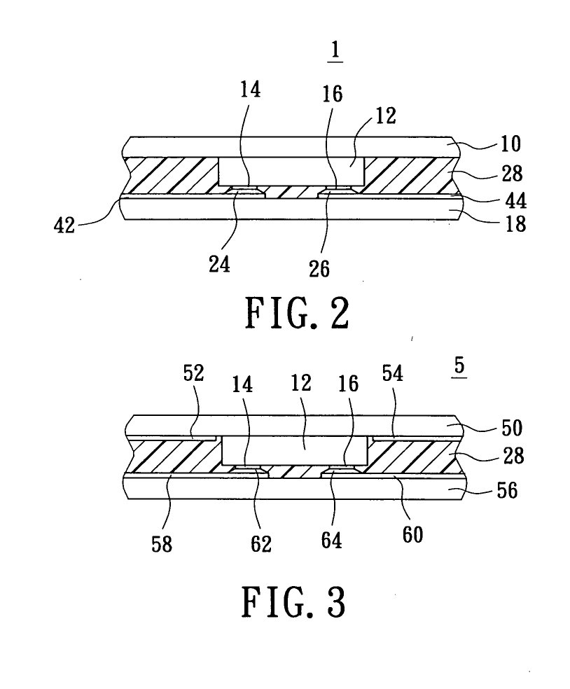

Referring to FIG. 2 for a schematic view of a RFID package structure in accordance with a second preferred embodiment of the present invention, the RFID package structure 1 comprises a first substrate 10, a RFID die 12, a second substrate 18, at least one antenna pattern 42, 44 and an adhesive 28.

The first substrate 10 and the second substrate 18 are made of a soft organic material or a fiber glass material, and the organic material includes a combination of polymer, polyester and other similar materials, or a hard material such as any combination of ceramics. The RFID die 12 includes at least one I/O pad 14, 16 disposed at a lower surface of the RFID die 12, and the RFID die 12 is installed at a lower surface of the first substrate 10, and at least one antenna pattern 42, 44 is formed at an upper surface of a second substrate 18, and each antenna pattern 42, 44 has a first connecting point 24, 26 and is connected to the I/O pad 14 through the first connecting point 24, 26 for electrically connecting the RFID die 12, and an adhesive 28 is filled between the first substrate 10 and the second substrate 18.

The major difference between the second preferred embodiment and the first preferred embodiment of the present invention resides on that the second substrate 18 of the first embodiment forms the first circuit patterns 20, 22 on its upper surface, and the first circuit patterns 20, 22 are simply electric circuits, and the second substrate 18 of the second preferred embodiment forms the antenna patterns 42, 44 including a complete radio frequency antenna circuit on its upper surface.

The RFID package structure in accordance with the second preferred embodiment of the present invention is characterized in that the RFID die 12 is packaged, and the radio frequency antenna patterns 42, 44 are laid directly on the second substrate 18 to achieve the effects of improving the moisture resisting capability, increasing the data reading rate, and providing better overall structural strength, and thus the second preferred embodiment of the invention provides a complete RFID transponder without requiring an additional process for connecting another external substrate (such as the third substrate 3 adopted in the first preferred embodiment).

Referring to FIG. 3 for a schematic view of a RFID package structure of a third preferred embodiment of the present invention, the RFID package structure 5 comprises a first substrate 50, at least one first antenna pattern 52, 54, a RFID die 12, a second substrate 56, at least one second antenna pattern 58, 60 and an adhesive 28.

The first substrate 50 and the second substrate 56 are made of a soft organic material or a glass fiber material, and the organic material includes a combination of polymer, polyester and other similar materials, or a hard material such as any combination of ceramics. The first substrate 50 forms the first antenna pattern 52, 54 on its lower surface, and the RFID die 12 has at least one I/O pad 14, 16 disposed at a lower surface of the RFID, and the RFID die 12 is installed at a lower surface of the first substrate 50 and the middle of the first antenna patterns 52, 54, and the second antenna patterns 58, 60 are formed on an upper surface of the second substrate 56, and each second antenna pattern 58, 60 has a first connecting point 62, 64, and is connected to the I/O pad 14, 16 through the first connecting point 62, 64 for electrically connecting the RFID die 12, and an adhesive 2 is filled between the first substrate 50 and the second substrate 56.

The RFID package structure in accordance with the third preferred embodiment of the present invention is characterized in that the RFID die 12 is packaged, and the first radio frequency antenna patterns 52, 54 are laid directly on the first substrate 50 and the second radio frequency antenna patterns 58, 60 are laid directly on the second substrate 56 to achieve the effects of improving the moisture resisting capability, increasing the data reading rate, and providing better overall structural strength, and thus the third preferred embodiment of the invention provides a complete RFID transponder without requiring an additional process for connecting another external substrate (such as the third substrate 3 adopted in the first preferred embodiment). Further, the first antenna patterns 52, 54 are laid on the first substrate 50 for dispersing an overcrowded antenna pattern on a specific substrate designed for different radio frequencies. Since the inductance of a radio frequency antenna is directly proportional to the number of coils, therefore the third preferred embodiment of the invention can reduce the overall packaging area for the manufacture of a multi-layer board, and the finished goods of the RFID transponder can be connected selectively to an active component or a passive component.

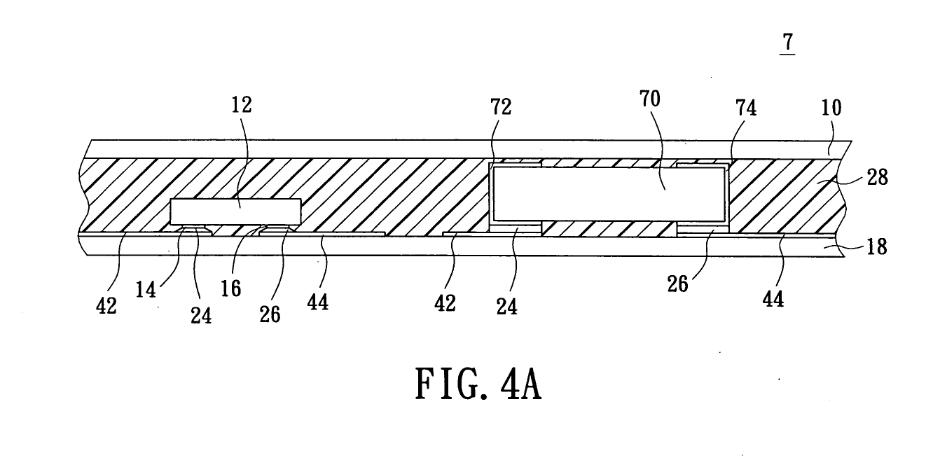

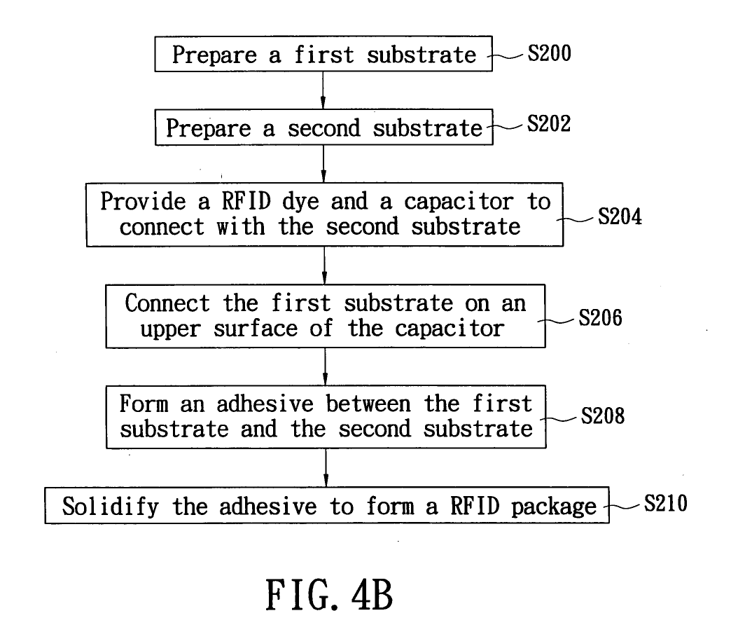

Referring to FIG. 4A for a schematic view of a RFID package structure of a fourth preferred embodiment of the present invention, the RFID package structure 7 comprises a first substrate 10, a RFID die 12, a second substrate 18, at least one antenna pattern 42, 44, a capacitor 70 and an adhesive 28.

The first substrate 10 and the second substrate 18 are made of a soft organic material or a glass fiber material, and the soft organic material includes a combination of polymer, polyester and other similar materials, or a hard material such as any combination of ceramics. The RFID die 12 comprises at least one I/O pad 14, 16 disposed at a lower surface of the RFID die 12, at least one antenna pattern 42, 44 formed on an upper surface of the a second substrate 18, and each antenna pattern 42, 44 has a first connecting point 24, 26 and is coupled to the I/O pad 14, 16 through the first connecting point 24, 26 for electrically connecting the RFID die 12, and a capacitor 70 installed at a lower surface of the first substrate 10, and the capacitor 70 has at least one conducting terminal 72, 74 coupled to the second substrate 18 through the first connecting point 24, 26 for electrically connecting the capacitor 70 with the second substrate 18, and an adhesive 28 filled between the first substrate 10 and the second substrate 18.

Referring to FIG. 4B for a flow chart of a manufacturing method of a RFID package structure 7 according to a fourth preferred embodiment of the present invention, the manufacturing procedure comprising the steps of: preparing a first substrate 10 (S200); preparing a second substrate 18 (S202), wherein the second substrate 18 forms at least one antenna pattern 42, 44 on its upper surface, and each antenna pattern 42, 44 has a first connecting point 24, 26; providing a RFID die 12 and a capacitor 70 for connecting the second substrate 18 (S204), wherein the RFID die 12 has at least one I/O pad 14, 16 on its lower surface, and the connecting process can be achieved by a soldering method or a baking method depending on the material of the first connecting point 24, 26, wherein the soldering method will be adopted if the first connecting points 24, 26 are made of a solder paste, and the baking method will be adopted if the first connecting points 24, 26 are made of a conductive adhesive.

While Step (S204) is being carried out, the first substrate 10 is combined to an upper surface of the capacitor by a soldering method or a baking method (S206), and an adhesive 28 is formed between the first substrate 10 and the second substrate 18 by an adhesion method or an ink-jet method, and the adhesive 28 can be a liquid epoxy resin, and the baking method is adopted to solidify the adhesive 28 to form the RFID package 1 (S208), and the adhesive 28 is solidified by the baking method to form the RFID package 7 (S210).

The RFID package structure in accordance with the fourth preferred embodiment of the present invention is characterized in that the RFID die 12 is packaged to achieve the effects of improving the moisture resisting capability, increasing the data reading rate, and providing better overall structural strength, and the radio frequency antenna patterns 42, 44 are laid directly on the second substrate 18. Further, the fourth preferred embodiment of the invention adds a capacitor 70 for producing LC circuit oscillations with the antenna pattern 42, 44 in the RFID package structure, since different frequencies can be achieved by changing the capacitance of the capacitor 70.

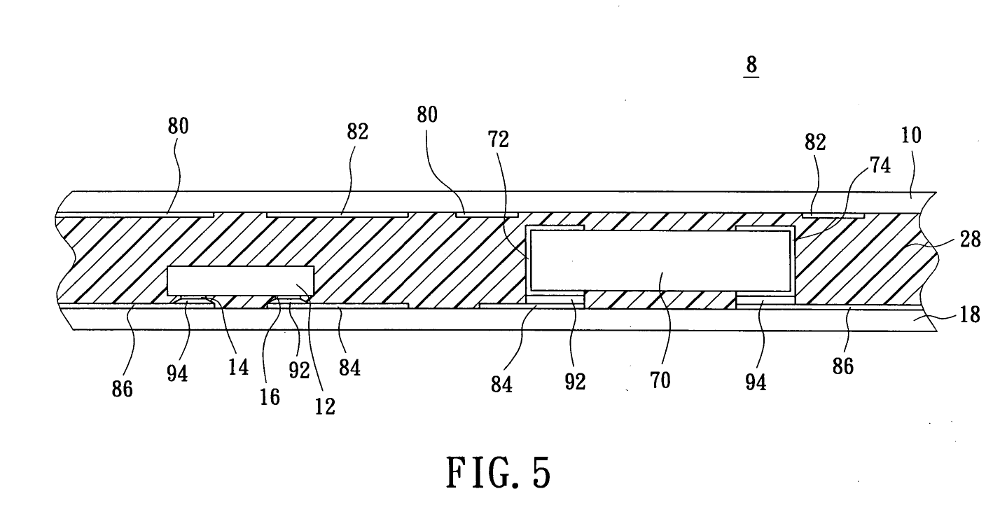

Referring to FIG. 5 for a schematic view of a RFID package structure in accordance with a fifth preferred embodiment of the present invention, the RFID package structure 8 comprises a first substrate 10, at least one first antenna pattern 80, 82, a RFID die 12, a second substrate 18, at least one second antenna pattern 84, 86, a capacitor 70 and an adhesive 28.

The first substrate 10 and the second substrate 18 are made of a soft organic material or a glass fiber material, and the soft organic material includes a combination of polymer, polyester and other similar materials, or a hard material such as any combination of ceramics. The first substrate 10 forms the first antenna pattern 80, 82 on its lower surface, and the RFID die 12 comprises: at least one I/O pad 14, 16 disposed at its lower surface; at least one second antenna pattern 84, 86 formed on an upper surface of the second substrate 18, and each second antenna pattern 84, 86 has a first connecting point 92, 94 and is coupled to the I/O pad 14, 16 through the first connecting point 92, 94 for electrically connecting the RFID die 12; a capacitor 70 installed at a lower surface of the first substrate 10, and the capacitor 70 has at least one conducting terminal 72, 74 coupled to the second substrate 18 through the first connecting point 92, 94 for electrically connecting the capacitor 70 with the second substrate 18; and an adhesive 28 filled between the first substrate 10 and the second substrate 18.

The RFID package structure in accordance with the fifth preferred embodiment of the present invention is characterized in that the RFID die 12 is packaged to achieve the effects of improving the moisture resisting capability, increasing the data reading rate, and providing better overall structural strength. Further, the first antenna patterns 80, 82 are laid on the first substrate 10 for dispersing an overcrowded antenna pattern on a specific substrate designed for different radio frequencies. Since the inductance of a radio frequency antenna is directly proportional to the number of coils, therefore the fifth preferred embodiment of the invention can reduce the whole packaging area for the manufacture of a multi-layer board, and the fifth preferred embodiment adds the capacitor 70 to produce LC circuit oscillations for the first antenna pattern 80, 82 in the RFID package structure, since different frequencies can be achieved by changing the capacitance of the capacitor 70.

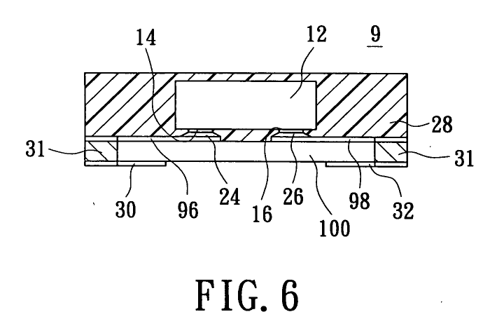

Referring to FIG. 6 for a schematic view of a RFID package structure with a single substrate of a first preferred embodiment of the present invention, the RFID package structure 9 with a single substrate comprises at least one circuit pattern 96, 98, a RFID die 12, a fourth substrate 100, and an adhesive 28.

The differences of the RFID package structure with a single substrate of this embodiment from that of the first preferred embodiment reside on that this embodiment does not come with a first substrate 10, and the adhesive 28 wraps the entire RFID package structure by using an ink-jet method or a printing method. Since the fourth substrate 100 and the circuit pattern 96, 98 do not come with a first substrate 10, therefore the manufacturing cost can be reduced. The rest of technical characteristics of the RFID package structure is the same as those of the first preferred embodiment, and thus will not be described here.

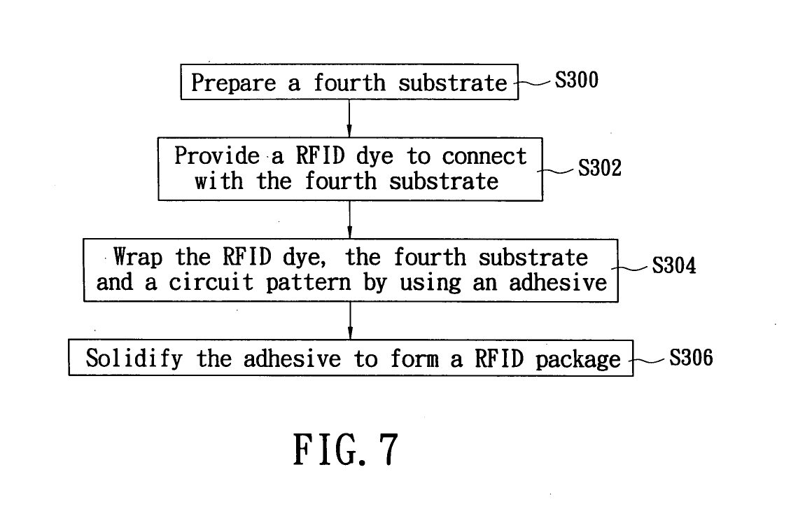

Referring to FIG. 7 for a flow chart of a manufacturing method of a RFID package structure with a single substrate according to the present invention, the manufacturing method comprises the steps of: preparing a fourth substrate 100 (S300), wherein the fourth substrate 100 forms at least one circuit pattern 96, 98 on its surface, and each circuit pattern 96, 98 has a first connecting point 24, 26; providing a RFID die 12 for connecting the fourth substrate 100 (S302), wherein the RFID die 12 has at least one I/O pad 14, 16 disposed at its lower surface, and the RFID die 12 is connected to the fourth substrate 100 by a soldering method or a baking method depending on the material of the first connecting point 24, 26, and the soldering method will be adopted if the first connecting points 24, 26 are made of a solder paste, and the baking method will be adopted if the first connecting points 24, 26 are made of a conductive adhesive.

After Step S302 is completed, an adhesive 28 is used for wrapping the RFID die 12, the fourth substrate 100 and the circuit patterns 96, 98 (S304), and the wrapping can be achieved by an ink-jet method or a printing method, and the adhesive 28 can be a liquid epoxy resin; and using the baking method to solidify the adhesive 28 to form the RFID package 9 (S306).

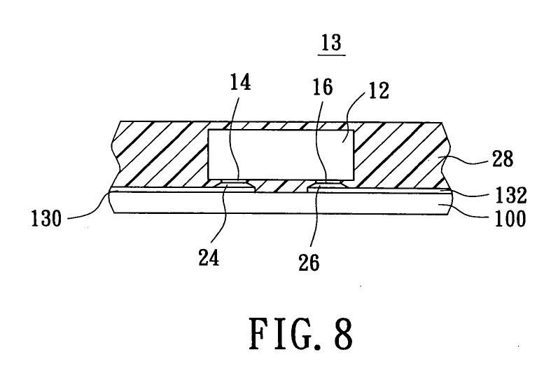

Referring to FIG. 8 for a schematic view of a RFID package structure with a single substrate of a second preferred embodiment of the present invention, the RFID package structure 13 with a single substrate comprises at least one antenna pattern 130, 132, a RFID die 12, a fourth substrate 100, and an adhesive 28.

The differences of the RFID package structure with a single substrate of this embodiment from that of the second preferred embodiment reside on that this embodiment does not come with a first substrate 10, and the adhesive 28 wraps the entire RFID package structure by using an ink-jet method or a printing method. Since the fourth substrate 100 and the antenna pattern 130, 132 do not come with a first substrate 10, therefore the manufacturing cost can be reduced. The rest of technical characteristics of the RFID package structure is the same as those of the first preferred embodiment, and thus will not be described here.

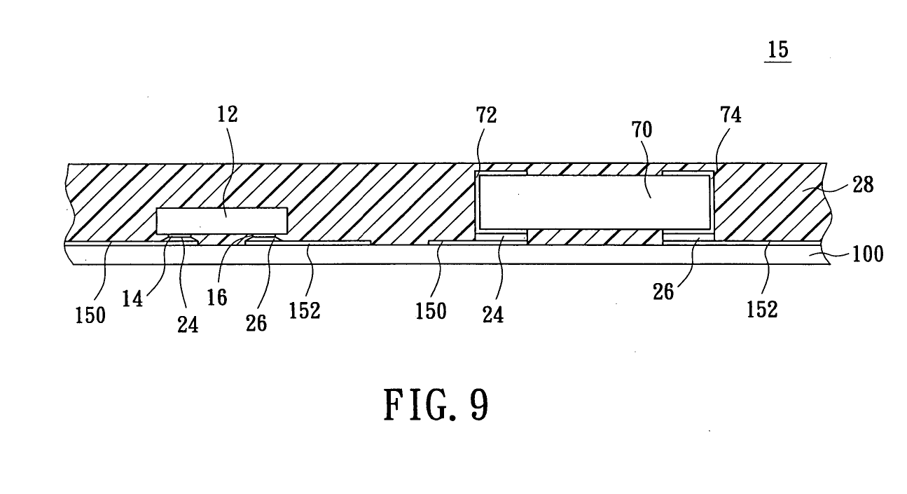

Referring to FIG. 9 for a schematic view of a RFID package structure with a single substrate of a third preferred embodiment of the present invention, the RFID package structure 15 with a single substrate comprises at least one antenna pattern 150, 152, a RFID die 12, a fourth substrate 100, a capacitor 70, at least one conducting terminal 72, 74 and an adhesive 28.

The differences of the RFID package structure with a single substrate in accordance with the third embodiment from that of the first preferred embodiment reside on that the third embodiment does not come with a first substrate 10, and the adhesive 28 wraps the entire RFID package structure by using an ink-jet method or a printing method. Since the fourth substrate 100 and the antenna pattern 150, 152 do not come with a first substrate 10, therefore the manufacturing cost can be reduced. The rest of technical characteristics of the RFID package structure is the same as those of the first preferred embodiment, and thus will not be described here.

The difference between the RFID package structure of the invention and the RFID transponder of the prior art resides on that the conventional RFID transponder is manufactured in the form of a barcode, and the RFID package structure of the invention is manufactured in the form of a package. The advantages of the invention include its convenience that allows users to put the RFID package freely in almost anywhere such as putting it in a carton, and attaching it on a carton or the back cover of a book, etc. Therefore, RFID package provides a more flexible range of applications than the conventional RFID transponder.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A robot system, comprising:
a robot that has a camera and a monitor;
a first remote station that can access said robot; and,
a second remote station that can access said robot and includes an arbitrator that can control access to said robot by said first and second remote stations.

2. The system of claim 1, wherein said arbitrator includes a notification mechanism.

3. The system of claim 1, wherein said arbitrator includes a timeout mechanism.

4. The system of claim 1, wherein said arbitrator includes a queue mechanism.

5. The system of claim 1, wherein said arbitrator includes a call back mechanism.

6. The system of claim 1, wherein said second remote station can access said robot, and said first.and second remote stations each have a priority and said arbitrator provides robot access to said remote station with a highest priority.

7. The system of claim 6, wherein said remote stations may be given priority as a local user, a doctor, a caregiver, a family member, or a service user.

8. The system of claim 1, wherein said robot operates in either an exclusive mode or a sharing mode.

9. The system of claim 1, wherein said first remote station transmits a communication for said robot that is initially transmitted to said second remote station.

10. The system of claim 1, wherein said first remote station sends a communication for said robot that is initially transmitted to said robot.

11. A robot system, comprising:
a robot that has a camera and a monitor;
a first remote station that can access said robot; and,
a second remote station that can access said robot and includes arbitration means for controlling access to said robot by said first and second remote stations.

12. The system of claim 11, wherein said arbitrator means includes notification means for notifying said first remote station that said second remote station is requesting access to said robot.

13. The system of claim 11, wherein said arbitrator means includes timeout means that creates a time interval in which one of said remote stations must relinquish access to said robot.

14. The system of claim 11, wherein said arbitrator means includes queue means for establishing a waiting list of remote stations seeking access to said robot.

15. The system of claim 11, wherein said arbitrator means includes call back means for providing a message to one of said remote stations that said robot can be accessed.

16. The system of claim 11, wherein said second remote station can access said robot, and said first and second remote stations each have a priority and said arbitrator means provides robot access to said remote station with a highest priority.

17. The system of claim 16, wherein said remote stations may be given priority as a local user, a doctor, a caregiver, a family member, or a service user.

18. The system of claim 11, wherein said robot operates in either an exclusive mode or a sharing mode.

19. The system of claim 11, wherein said first remote station transmits a communication for said robot that is initially transmitted to said second remote station.

20. The system of claim 11, wherein said first remote station sends a communication for said robot that is initially transmitted to said robot.

21. A method for controlling access to a remote controlled robot, comprising:
transmitting a request to access a robot from a first remote station;
determining whether the first remote station should have access to the robot at a second remote station that can access the robot;
allowing access to the robot; and, transmitting video images between the robot and the first remote station.

22. The method of claim 21, further comprising requesting access to the robot from the second remote station and notifying the first remote station of the request.

23. The method of claim 22, wherein the second remote station creates a time interval in which the first remote station must relinquish access to the robot.

24. The method of claim 22, wherein the request from the second remote station is placed in a waiting list queue.

25. The method of claim 21, further comprising transmitting a call back message from the second remote station to the first remote station to indicate the granting of access to the robot.

26. The method of claim 21, wherein the access request includes a priority that. is evaluated by the second remote station to determine access to the robot.

27. The method of claim 26, wherein the remote stations may be given priority as a local user, a doctor, a caregiver, a family member, or a service user.

28. The method of claim 25, wherein the robot operates in either an exclusive mode or a sharing mode.

29. The method of claim 25, wherein the access request is initially transmitted to the second remote station.

30. The method of claim 25, wherein the access request is initially transmitted to the robot.

31. A robot system, comprising:
a broadband network;
a robot that is coupled to said broadband network, and has a camera and a monitor;
a first remote station that can access said robot through said broadband network; and,
a second remote station that can access said robot and includes an arbitrator that can control access to said robot by said first and second remote stations.

32. The system of claim 31 wherein said arbitrator includes a notification mechanism.

33. The system of claim 31, wherein said arbitrator includes a timeout mechanism.

34. The system of claim 31, wherein said arbitrator includes a queue mechanism.

35. The system of claim 31, wherein said arbitrator includes a call back mechanism.

36. The system of claim 31, wherein said second remote station can access said robot, and said first and second remote stations each have a priority and said arbitrator provides robot access to said remote station with a highest priority.

37. The system of claim 36, wherein said remote stations may be given priority as a local user, a doctor, a caregiver, a family member, or a service user.

38. The system of claim 31, wherein said robot operates in either an exclusive mode or a sharing mode.

39. The system of claim 31, wherein said first remote station transmits a communication for the robot that is initially transmitted to said second remote station.

40. The system of claim 31, wherein said first remote station sends a communication for said robot that is initially transmitted to said robot.

41. A robot system, comprising:
a broadband network;
a robot that is coupled to said broadband network, and has a camera and a monitor;
a first remote station that can access said robot through said broadband network; and,
a second remote station that can access said robot and includes arbitration means for controlling access to said robot by said first and second remote stations.

42. The system of claim 41, wherein said arbitrator means includes notification means for notifying said first remote station that said second remote station is requesting access to said robot.

43. The system of claim 41, wherein said arbitrator means includes timeout means that creates a time interval in which one of said remote stations must relinquish access to said robot.

44. The system of claim 41, wherein said arbitrator means includes queue means for establishing waiting list of remote stations seeking access to said robot.

45. The system of claim 41, wherein said arbitrator means includes call back means for providing a message to one of said remote stations that said robot can be accessed.

46. The system of claim 41, wherein said second remote station can access said robot, and said first and second remote stations each have a priority and said arbitrator means provides robot access to said remote station with a highest priority.

47. The system of claim 46, wherein said remote stations may be given priority as a local user, a doctor, a caregiver, a family member, or a service user.

48. The system of claim 41, wherein said robot operates in either an exclusive mode or a sharing mode.

49. The system of claim 41, wherein said first remote station transmits a communication for said robot that is initially transmitted to said second remote station.

50. The system of claim 41, wherein said first remote station sends a communication for said robot that is initially transmitted to said robot.

51. A method for controlling access to a remote controlled robot, comprising:
transmitting a request to access a robot from a first remote station through a broadband network;
determining whether the first remote station should have access to the robot at a second remote station that can access the robot;
allowing access to the robot through the broadband network; and,
transmitting video images between the robot and the first remote station between the broadband network.

52. The method of claim 51, further comprising requesting access to the robot from the second remote station and notifying the first remote station of the request.

53. The method of claim 52, wherein the second remote station creates a time interval in which the first remote station must relinquish access to the robot.

54. The method of claim 52, wherein the request from the second remote station is placed in a waiting list queue.

55. The method of claim 51, further comprising transmitting a call back message from the second remote station to the first remote station to indicate the granting of access to the robot.

56. The method of claim 51, wherein the access request includes a priority that is evaluated by the second remote station to determine access to the robot.

57. The method of claim 56, wherein the remote stations may be given priority as a local user, a doctor, a caregiver, a family member, or a service user.

58. The method of claim 51, wherein the robot operates in either an exclusive mode or a sharing mode.

59. The method of claim 51, wherein the access request is initially transmitted to the second remote station.

60. The method of claim 51, wherein the access request is initially transmitted to the robot.

61. The method of claim 1, wherein the robot is mobile.

62. The system of claim 11, wherein said robot is mobile.

63. The system of claim 21, wherein said robot is mobile.

64. The system of claim 31, wherein said robot is mobile.

65. The system of claim 41, wherein said robot is mobile.

66. The method of claim 51, wherein the robot is mobile.
